(19) United States
(12) Patent Application Publication
(10) Pub. No.: US 2013/0146934 A1
(43) Pub. Date: Jun. 13, 2013

(54) LIGHT-EMITTING DIODE DEVICE

(71) Applicant: Chi Mei Lighting Technology Corp., Tainan (TW)

(72) Inventors: Chung-Hsin Lin, Tainan (TW); Shin-Jia Chiou, Tainan (TW); Chi-Lung Wu, Tainan (TW); Jui-Chun Chang, Tainan (TW); Chang-Shin Chu, Tainan (TW)

(73) Assignee: Chi Mei Lighting Technology Corp., Tainan (TW)

(21) Appl. No.: 13/710,142

(22) Filed: Dec. 10, 2012

(30) Foreign Application Priority Data
Dec. 9, 2011 (TW) 100145606

(51) Int. Cl. H01L 33/38

(52) U.S. Cl. CPC H01L 33/38
USPC 257/99

(57) ABSTRACT

A light-emitting diode device includes a substrate, an epitaxial layer and a first electrode. The epitaxial layer is disposed on the substrate. The first electrode is disposed on the epitaxial layer and includes a connecting portion and a conductive finger. The conductive finger has a first end and a second end, and the first end is connected to the connecting portion. At least one portion of the conductive finger is tapered along an extending direction of the conductive finger.

### CROSS-REFERENCE TO RELATED APPLICATION

This non-provisional application claims priority under 35 U.S.C. §119(a) on Patent Application No. 100145606 filed in Taiwan R.O.C. on Dec. 9, 2011, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates generally to a light-emitting diode (LED) device, and more particularly to an LED device for improving uniformity of luminous intensity.

### BACKGROUND OF THE INVENTION

A light-emitting diode (LED) is a light-emitting element formed of a semiconductor material. The LED belongs to cold light emission, has advantages of low power consumption, long service life and high response speed, and is easily fabricated into an extremely small or array-type element owing to its small volume. Therefore, with constant development of technologies in recent years, the LED has been widely applied to indicator lamps of computers or household appliances, back light sources of liquid crystal displays, and traffic signs or vehicle indicator lamps.

FIG. 1 shows a conventional LED device 1, including a first electrode 11, an epitaxial layer 12, a bonding layer 13, a conductive substrate 14 and a second electrode 15 which are stacked in sequence. FIG. 2 is a schematic top view of the LED device 1, where the first electrode 11 includes a conductive pad 111 and a conductive finger 112 connected to each other. The LED device 1 emits light by energizing the conductive pad 111 of the first electrode 11 and another conductive pad of the second electrode 15. When the first electrode 11 is energized, a current is input through the conductive pad 111, causing a large current at the conductive pad 111. However, when the current flows from the conductive pad 111 into the conductive finger 112, since the conductive metal area decreases drastically, current crowding occurs at the junction between the conductive pad 111 and the conductive finger 112. Consequently, a large current directly flows from a region near the conductive pad 111 to the epitaxial layer 12 there-below, resulting in that the luminous intensity of the region near the conductive pad 111 is higher than that of other regions, that is, in the example of FIG. 2, the luminance of the upper half of the LED device 1 is higher than that of the lower half.

To solve the problem of non-uniform luminous intensity resulting from non-uniform current spreading, in the related art, a current block (CB) structure is disposed in the LED device 1. The CB structure is an insulator, which can force the current to flow through two sides thereof so as to alleviate the phenomenon of non-uniform current spreading. As shown in FIG. 3A, the LED device 1a further includes a CB structure 16. FIG. 3B is a schematic top view of the first electrode 11 and the CB structure 16. The CB structure 16 is disposed between the epitaxial layer 12 and the bonding layer 13, and can force the current to flow into regions that are not right below the conductive pad 111, so as to uniformly spread the current, thereby achieving uniform luminous intensity.

However, experimental results show that if only the CB structure 16 is disposed, the problem of non-uniform luminous intensity can be alleviated slightly, but the fundamental problem of current crowding cannot be solved, and therefore, uniformity of luminous intensity cannot be improved greatly.

Therefore, how to provide an LED device that can solve the fundamental problem of current crowding to greatly improve uniformity of luminous intensity is an urgent task to be solved.

### SUMMARY OF THE INVENTION

Accordingly, in one aspect, the present invention is directed to an LED device that can solve the fundamental problem of current crowding to greatly improve uniformity of luminous intensity.

In one embodiment, an LED device according to the present invention includes a substrate, an epitaxial layer and a first electrode. The epitaxial layer is disposed on the substrate. The first electrode is disposed on the epitaxial layer, and includes a connecting portion and a conductive finger. The conductive finger has a first end and a second end, the first end is connected to the connecting portion, and at least one portion of the conductive finger is tapered along an extending direction of the conductive finger.

In one embodiment, an LED device according to the present invention includes a substrate, an epitaxial layer, a first electrode and at least one CB structure. The epitaxial layer is disposed on the substrate. The first electrode is disposed on the epitaxial layer. The CB structure is disposed corresponding to the first electrode, and located between the substrate and the first electrode, and includes a barrier connecting portion and a barrier finger. The barrier finger has a third end and a fourth end, the third end is connected to the barrier connecting portion, and at least one portion of the barrier finger is tapered along an extending direction of the barrier finger.

In one embodiment, an LED device according to the present invention includes a substrate, an epitaxial layer, a first electrode and at least one CB structure. The epitaxial layer is disposed on the substrate. The first electrode is disposed on the epitaxial layer, and includes a connecting portion and a conductive finger. The conductive finger has a first end and a second end, the first end is connected to the connecting portion, and at least one portion of the conductive finger is tapered along an extending direction of the conductive finger. The CB structure is disposed corresponding to the first electrode, and located between the substrate and the first electrode, and includes a barrier connecting portion and a barrier finger. The barrier finger has a third end and a fourth end, the third end is connected to the barrier connecting portion, and at least one portion of the barrier finger is tapered along an extending direction of the barrier finger.

Based on the above, in the LED device according to embodiments of the present invention, at least one portion of the conductive finger is tapered along an extending direction of the conductive finger, that is, the change in width from the connecting portion to the conductive finger is reduced greatly. In this way, when a current flows from the connecting portion into the conductive finger, current crowding near the junction between the connecting portion and the conductive finger can be avoided, and a large amount of current still flows from the connecting portion to the conductive finger, and does not directly flow to the epitaxial layer there-below, thereby solving the fundamental problem of current crowding, greatly improving uniformity of current spreading, and further improving uniformity of luminous intensity. Moreover, in the LED device of the present invention, the CB structure may further be disposed to improve uniformity of current spreading and luminous intensity. Furthermore, since at least one portion of the barrier finger of the CB structure is tapered along an extending direction of the barrier finger, that is, the CB structure corresponds to the change in width of the conductive finger, the function of the CB structure can be fully exploited, thereby further improving uniformity of current spreading and luminous intensity.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a schematic view of a conventional LED device;

FIG. 2 is a schematic top view of the LED device shown in FIG. 1;

FIG. 3A is a schematic view of a conventional LED device having a CB structure;

FIG. 3B is a schematic top view of a first electrode and a CB structure shown in FIG. 3A;

FIG. 4 to FIG. 8 are schematic views of different aspects of an LED device according to a preferred embodiment of the present invention;

FIG. 9 and FIG. 10 are schematic views of different aspects of a first electrode of an LED according to a preferred embodiment of the present invention;

FIG. 11 to FIG. 13 are schematic views of different aspects of a first electrode and a CB structure of an LED according to a preferred embodiment of the present invention; and

FIG. 14 is a schematic view illustrating comparison of current densities of the related art and an embodiment of the present invention.

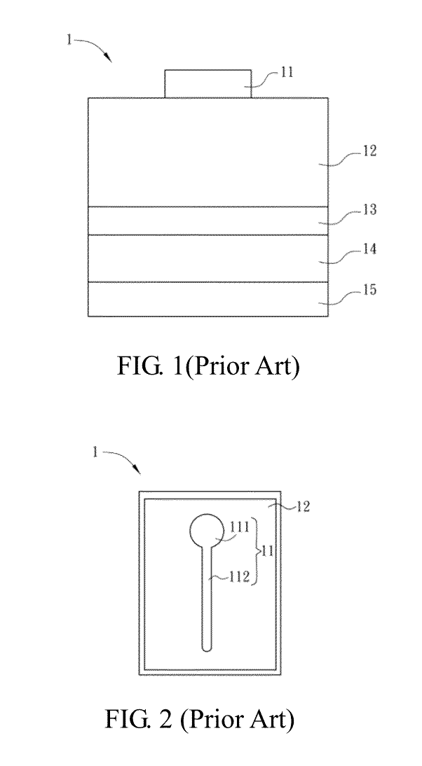

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

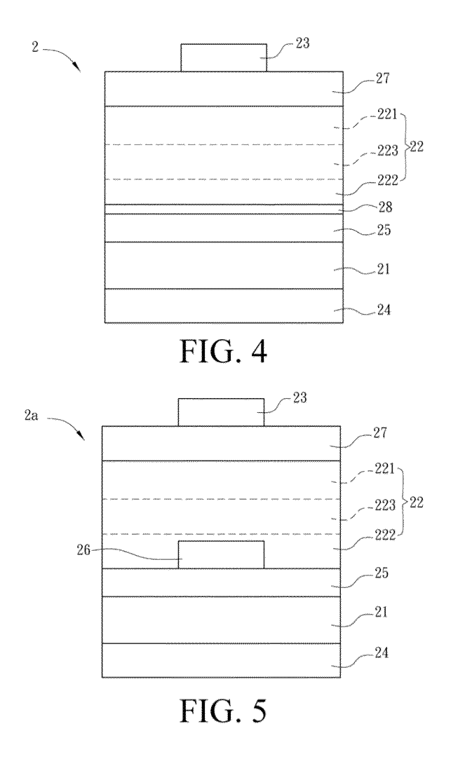

The description will be made as to the embodiments of the present invention in conjunction with the accompanying drawings in FIGS. 4-14. Wherever possible, the same reference numbers are used in the drawings and the description to refer to the same or like parts. In accordance with the purposes of this invention, as embodied and broadly described herein, this invention, in one aspect, relates to an LED device for improving uniformity of luminous intensity.

FIG. 4 is a schematic view of an LED device 2 according to a preferred embodiment of the present invention. The LED device 2 includes a substrate 21, an epitaxial layer 22, a first electrode 23, a second electrode 24, a bonding layer 25 and a light-transmissive conductive layer 27.

The substrate 21 is a conductive substrate including a conductive material, and the conductive substrate may use a material to help dissipate heat. The substrate 21 may include a conductive material or a mixture of conductive and nonconductive materials. The conductive material is, for example, SiC, Si or Cu. The substrate 21 is, for example, a SiC substrate, a Si substrate or a Cu substrate.

The epitaxial layer 22 is disposed on the substrate 21. Herein, the epitaxial layer 22 is disposed “on” the substrate 21 means that the epitaxial layer 22 directly contacts the substrate 21 or is located on another layer that is arranged on the substrate 21. Herein, the bonding layer 25 is located between the epitaxial layer 22 and the substrate 21, so that the epitaxial layer 22 is disposed on the substrate 21.

The epitaxial layer 22 may be any semiconductor layer, and for example, includes a first semiconductor layer 221 and a second semiconductor layer 222, where the first semiconductor layer 221 and the second semiconductor layer 222 have different conductivity types. In this embodiment, the first semiconductor layer 221 is N-type, and the second semiconductor layer 222 is P-type. The material of the epitaxial layer 22 may vary with the function of the LED, for example, diode for emitting blue light, diode for emitting green light, diode for emitting red light and the like. The material of the epitaxial layer 22 may be, for example, selected from GaN-series materials such as InGaN and AlGaN or AlInGaP-series materials. In addition, the epitaxial layer 22 may further include a multiple quantum well (MQW) layer 223 for generating desired light, where the MQW layer 223 is sandwiched between the first semiconductor layer 221 and the second semiconductor layer 222.

The bonding layer 25 includes a conductive material for electrical conducting the epitaxial layer 22 and the substrate 21. The conductive material may include, for example, but not limited to, Cr, Pt, Au, Ti, Sn, alloy or an combination thereof.

In addition, the LED device 2 may further include a reflector layer 28, which may be disposed between the epitaxial layer 22 and the substrate 21 to reflect light generated by the epitaxial layer 22 and emitted to the substrate 21, so as to increase the light extracting efficiency. Herein, the reflector layer 28 is located between the epitaxial layer 22 and the bonding layer 25, and may be formed of a conductive material including, but not limited to, Ni, Ag, Al alloy or an combination thereof. The reflector layer 28 may be disposed or not disposed according to actual demands.

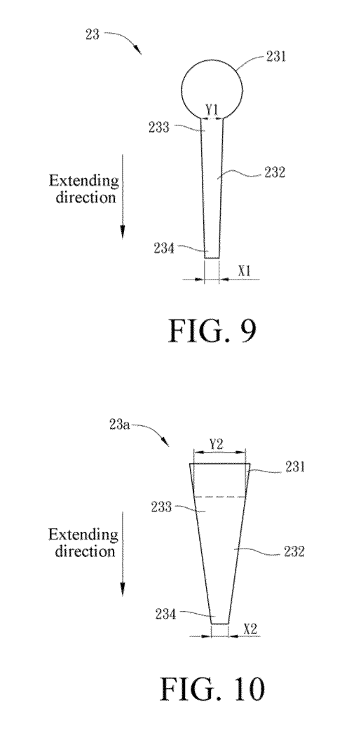

The first electrode 23 is disposed on the epitaxial layer 22. Herein, the first electrode 23 is disposed on a light-transmissive conductive layer 27 that is arranged on the epitaxial layer 22. The light-transmissive conductive layer 27 can facilitate current spreading and form an ohmic contact. The material of the light-transmissive conductive layer 27 may include, for example, a transparent conductive oxide (TCO) such as ITO. FIG. 9 is a schematic top view of the first electrode 23 shown in FIG. 4. Referring to FIG. 9, the first electrode 23 includes a connecting portion 231 and a conductive finger 232, the conductive finger 232 has a first end 233 and a second end 234, and the first end 233 is connected to the connecting portion 231. Herein, the connecting portion 231 is a conductive pad for wire bonding; the conductive finger 232 is, for example, an elongated conductive finger for uniformly spreading the current.

At least one portion of the conductive finger 232 is tapered along an extending direction of the conductive finger 232. In this embodiment, a width X1 of the second end 234 of the conductive finger 232 is smaller than a width Y1 of the first end 233. Herein, the conductive finger 232 is tapered from the first end 233 to the second end 234. In other words, compared to the related art, the change in width from the connecting portion 231 of the first electrode 23 to the first end 233 and the second end 234 of the conductive finger 232 is reduced greatly. In this way, when a current flows from the connecting portion 231 into the conductive finger 232, current crowding near the junction between the connecting portion 231 and the conductive finger 232 can be avoided, and a large amount of current still flows from the connecting portion 231 to the conductive finger 232, which avoids the problem in the related art that the current directly flows into the epitaxial layer 22 below the region near the connecting portion 231, thereby greatly improving uniformity of current spreading, and further improving uniformity of luminous intensity.

However, since the conductive finger 232 generally uses a metal material to achieve desired conductive characteristics, and most of metal materials have a light shielding characteristic, although the design of increasing the width of the first end 233 of the conductive finger 232 facilitates uniform current spreading, if the width of the first end 233 of the conductive finger 232 is designed too large, the light shielding area of the conductive finger 232 will be too large, leading to a decrease in the light extraction efficiency. Therefore, the width Y1 may have a preferable range, for example, the width Y1 needs to be greater than the width X1 and smaller than or equal to 2 times the width X1 of the second end, and preferably, the width Y1 is smaller than or equal to 1.5 times the width X1 of the second end.

The shapes of the connecting portion 231 and the conductive finger 232 of the first electrode 23 shown in FIG. 9 are merely provided as an example, but are not intended to limit the present invention. In other aspects, for example, the conductive finger 232 of the first electrode 23 may be rectilinear, L-shaped or U-shaped; alternatively, the first electrode 23 may include a plurality of conductive fingers 232.

In addition, FIG. 10 shows a first electrode 23a in another aspect, which includes a connecting portion 231 and a conductive finger 232, and is tapered proportionally from the connecting portion 231 to the conductive finger 232. In this aspect, in the first electrode 23a, a region for wire bonding is defined as the connecting portion 231, and a region connected to the connecting portion 231 is defined as the conductive finger 232. A first end 233 of the conductive finger 232 is connected to the connecting portion 231 and has a width Y2, a second end 234 of the conductive finger 232 has a width X2, and the width Y2 is greater than the width X2.

Referring to FIG. 4 again, the second electrode 24 is disposed below the substrate 21, so that the substrate 21 is located between the first electrode 23 and the second electrode 24. Herein, the first electrode 23 is N-type, and the second electrode 24 is P-type.

FIG. 5 is a schematic view of another LED device 2a according to a preferred embodiment of the present invention. Different from the LED device 2 shown in FIG. 4, the LED device 2a further includes at least one CB structure 26, which is disposed corresponding to the first electrode 23, and may be located between the first electrode 23 and the epitaxial layer 22 or between the epitaxial layer 22 and the substrate 21. Herein, the CB structure 26 is, for example, located between the epitaxial layer 22 and the substrate 21, and particularly located between the epitaxial layer 22 and the bonding layer 25. The CB structure 26 includes an insulating material, and is an insulator herein. The CB structure 26 can force the current from the first electrode 23 to flow through two sides thereof so as to alleviate the phenomenon of non-uniform current spreading.

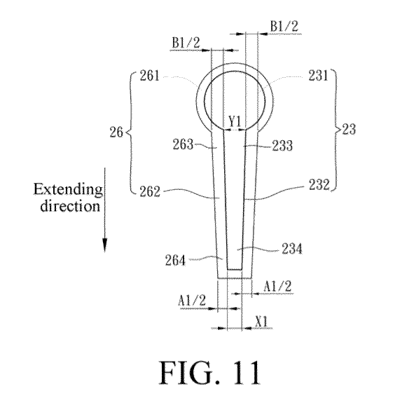

In this embodiment, the CB structure 26 may have one particular shape. FIG. 11 is a schematic top view of the first electrode 23 and the CB structure 26 shown in FIG. 5. Referring to FIG. 11, the CB structure 26 includes a barrier connecting portion 261 and a barrier finger 262, the barrier finger 262 has a third end 263 and a fourth end 264, the third end 263 is connected to the barrier connecting portion 261, and at least one portion of the barrier finger 262 is tapered along an extending direction of the barrier finger 262. Herein, the barrier finger 262 is tapered from the third end 263 to the fourth end 264. Whereby, the shapes of the barrier connecting portion 261 and the barrier finger 262 of the CB structure 26 correspond to those of the connecting portion 231 and the conductive finger 232 of the first electrode 23, so that uniformity of current spreading can be improved, thereby improving uniformity of luminous intensity. In this embodiment, a projection of the connecting portion 231 of the first electrode 23 falls within the barrier connecting portion 261 of the CB structure 26, and the extending direction of the conductive finger 232 of the first electrode 23 is the same as the extending direction of the barrier finger 262 of the CB structure 26.

Moreover, in this embodiment, a width of the third end 263 of the barrier finger 262 is greater than a width of the first end 233 of the conductive finger 232, and a width of the fourth end 264 of the barrier finger 262 is greater than a width of the second end 234 of the conductive finger 232, so that the current spreading effect may be enhanced.

However, since the current does not easily flow through the region of the epitaxial layer 22 corresponding to the CB structure 26, although the CB structure 26 facilitates uniform current spreading, if the CB structure 26 is designed too large, the area of the epitaxial layer 22 through which the current flows will decrease, leading to a decrease in the luminous efficiency. Therefore, the widths of the third end 263 and the fourth end 264 of the CB structure 26 may have a preferable range. For example, a difference B1 between the width of the third end 263 and the width of the first end 233 (B1/2 in the drawing represents a width difference of a single side) is greater than a difference A1 between the width of the fourth end 264 and the width of the second end 234 (A1/2 in the drawing represents a width difference of a single side), and the difference B1 is smaller than or equal to 2 times the difference A1, and preferably, the difference B1 is smaller than or equal to 1.5 times the difference A1.

The shapes of the barrier connecting portion 261 and the barrier finger 262 of the CB structure 26 shown in FIG. 11 are merely provided as an example, but are not intended to limit the present invention. In other aspects, for example, the barrier finger of the CB structure may be rectilinear, L-shaped or U-shaped; alternatively, the CB structure may include a plurality of barrier fingers. In addition, the shape of the first electrode 23 corresponds to that of the CB structure 26.

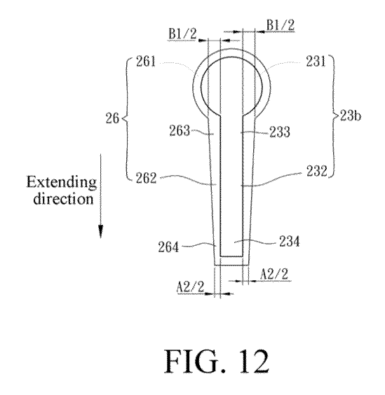

FIG. 12 is a schematic top view of another aspect of the first electrode 23b and the CB structure 26 shown in FIG. 5. As shown in FIG. 12, the first electrode 23b has a connecting portion 231 and a conductive finger 232, but the first end 233 and the second end 234 of the conductive finger 232 have the same width, and the conductive finger 232 is not tapered but is rectangular. In addition, in this aspect, the CB structure 26 is tapered from the third end 263 to the fourth end 264. Accordingly, a width difference B1 between the CB structure 26 and the conductive finger 232 is greater than a width difference A2, and the width difference B1 is smaller than or equal to 2 times the width difference A2, and preferably, the width difference B1 is smaller than or equal to 1.5 times the width difference A2.

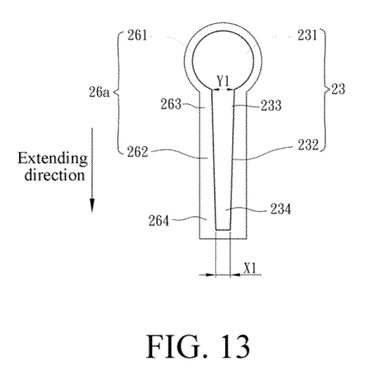

FIG. 13 is a schematic top view of another aspect of the first electrode 23 and the CB structure 26a shown in FIG. 5. As shown in FIG. 13, the first electrode 23 is the same as the first electrode 23 shown in FIG. 9, so the details will not be described herein again. In this aspect, the third end 263 and the fourth end 264 of the CB structure 26a have the same width, and the barrier finger 262 is not tapered but is rectangular.

The technical features corresponding to FIG. 11 to FIG. 13 may also be applied to the following aspects of the LED device.

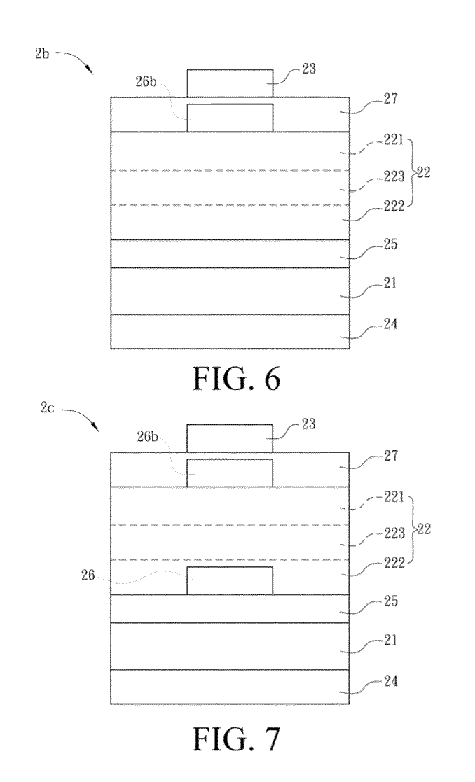

FIG. 6 is a schematic view of another LED device 2b according to a preferred embodiment of the present invention. Different from the LED device 2a shown in FIG. 5, the CB structure 26b of the LED device 2b is located between the first electrode 23 and the epitaxial layer 22. In addition, the light-transmissive conductive layer 27 is located between the first electrode 23 and the epitaxial layer 22, and covers the CB structure 26b. The CB structure 26b and the first electrode 23 have the features as shown in one of FIG. 11 to FIG. 13.

FIG. 7 is a schematic view of another LED device 2c according to a preferred embodiment of the present invention. Different from the LED devices described above, the LED device 2c includes a plurality of CB structures, and this embodiment is equivalent to including the CB structures 26 and 26b in FIG. 5 and FIG. 6. At least one of the CB structures 26 and 26b and the first electrode 23 may have the features as shown in one of FIG. 11 to FIG. 13.

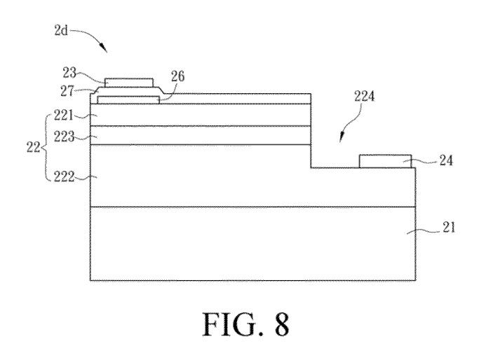

The LED device is described above by taking a vertical LED as an example, while the technical features of the present invention may also be applied to a lateral LED. FIG. 8 is a schematic view of another LED device 2d according to a preferred embodiment of the present invention, where the LED device 2d is a lateral LED. The LED device 2d includes a substrate 21, an epitaxial layer 22, a first electrode 23, a second electrode 24, a CB structure 26 and a light-transmissive conductive layer 27. The material of the substrate 21 may include, for example, sapphire, SiC, GaP or Si, and herein, the substrate 21 is, for example, a sapphire substrate. The first electrode 23 is a P-type electrode, and the second electrode 24 is an N-type electrode. In addition, the second electrode 24 is disposed in a notch 224 of the epitaxial layer 22 and conducted to the second semiconductor layer 222 of the epitaxial layer 22; the first electrode 23 is conducted to the first semiconductor layer 221 through the light-transmissive conductive layer 27; the epitaxial layer 22 may further include an MQW layer 223 sandwiched between the first semiconductor layer 221 and the second semiconductor layer 222. Herein, the first semiconductor layer 221 is P-type, and the second semiconductor layer 222 is N-type.

It should be noted that, at least one of the first electrodes and the CB structures of the LED devices of all the above aspects may have the technical features of the first electrodes or the CB structures as shown in FIG. 9 to FIG. 13, details of which will not be described herein again.

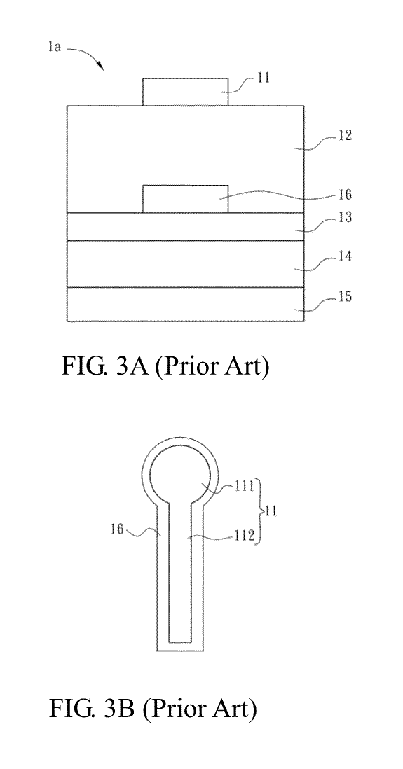

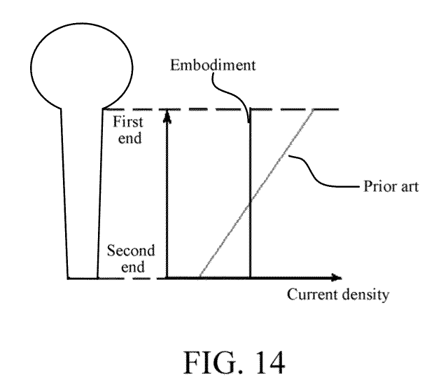

FIG. 14 is a schematic view illustrating comparison of current densities of the related art and an embodiment of the present invention. In the related art, for the structure shown in FIG. 3B, since the widths of the conductive finger and the barrier finger remain unchanged along the extending direction, the current density is the highest at the first end of the conductive finger, and gradually decreases toward the second end of the conductive finger, resulting in non-uniform luminance of the LED device in the related art. In the present invention, since at least one portion of the conductive finger and the barrier finger is tapered along an extending direction of the conductive finger and the barrier finger, the current crowding phenomenon in the related art can be alleviated. It may be found from FIG. 14 that through the design of the present invention, the current density may remain unchanged along the extending direction of the conductive finger and the barrier finger, thereby alleviating the current crowding phenomenon.

Based on the above, in the LED device of the present invention, at least one portion of the conductive finger is tapered along an extending direction of the conductive finger, for example, tapered from the first end to the second end, that is, the change in width from the connecting portion to the first end and the second end of the conductive finger is reduced greatly. In this way, when a current flows from the connecting portion into the conductive finger, current crowding near the junction between the connecting portion and the conductive finger can be avoided, and a large amount of current still flows from the connecting portion to the conductive finger, which avoids the problem in the related art that the current directly flows into the epitaxial layer below the region near the connecting portion, thereby solving the fundamental problem of current crowding, greatly improving uniformity of current spreading, and further improving uniformity of luminous intensity. Moreover, in the LED device of the present invention, the CB structure may further be disposed to improve uniformity of current spreading and luminous intensity. Furthermore, since at least one portion of the barrier finger of the CB structure is tapered along an extending direction of the barrier finger, that is, the CB structure corresponds to the change in width of the conductive finger, the function of the CB structure can be fully exploited, thereby further improving uniformity of current spreading and luminous intensity.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) device, comprising:
a substrate;
an epitaxial layer, disposed on the substrate; and
a first electrode, disposed on the epitaxial layer, and comprising a connecting portion and a conductive finger, wherein the conductive finger has a first end and a second end, the first end is connected to the connecting portion, and at least one portion of the conductive finger is tapered along an extending direction of the conductive finger.

2. The LED device according to claim 1, wherein the conductive finger is tapered from the first end to the second end.

3. The LED device according to claim 1, wherein a width of the first end of the conductive finger is greater than a width of the second end of the conductive finger and smaller than or equal to 2 times the width of the second end of the conductive finger.

4. The LED device according to claim 1, further comprising:
at least one current block (CB) structure, disposed corresponding to the first electrode, and located between the first electrode and the epitaxial layer or between the epitaxial layer and the substrate.

5. A light-emitting diode (LED) device, comprising:
a substrate;
an epitaxial layer, disposed on the substrate;
a first electrode, disposed on the epitaxial layer; and
at least one current block (CB) structure, disposed corresponding to the first electrode, located between the substrate and the first electrode, and comprising a barrier connecting portion and a barrier finger, wherein the barrier finger has a third end and a fourth end, the third end is connected to the barrier connecting portion, and at least one portion of the barrier finger is tapered along an extending direction of the barrier finger.

6. The LED device according to claim 5, wherein the barrier finger is tapered from the third end to the fourth end.

7. The LED device according to claim 5, wherein the first electrode comprises a connecting portion and a conductive finger, the conductive finger has a first end and a second end, the first end is connected to the connecting portion, a width of the third end is greater than a width of the first end, a width of the fourth end is greater than a width of the second end, and a difference between the width of the third end and the width of the first end is greater than a difference between the width of the fourth end and the width of the second end and smaller than or equal to 2 times the difference between the width of the fourth end and the width of the second end.

8. The LED device according to claim 5, wherein the CB structure is located between the first electrode and the epitaxial layer or between the epitaxial layer and the substrate.

9. A light-emitting diode (LED) device, comprising:
a substrate;
an epitaxial layer, disposed on the substrate;
a first electrode, disposed on the epitaxial layer, and comprising a connecting portion and a conductive finger, wherein the conductive finger has a first end and a second end, the first end is connected to the connecting portion, and at least one portion of the conductive finger is tapered along an extending direction of the conductive finger; and
at least one current block (CB) structure, disposed corresponding to the first electrode, and located between the substrate and the first electrode, and comprising a barrier connecting portion and a barrier finger, wherein the barrier finger has a third end and a fourth end, the third end is connected to the barrier connecting portion, and at least one portion of the barrier finger is tapered along an extending direction of the barrier finger.

10. The LED device according to claim 9, wherein the conductive finger is tapered from the first end to the second end, and the barrier finger is tapered from the third end to the fourth end.

11. The LED device according to claim 9, wherein a width of the first end is greater than a width of the second end and smaller than or equal to 2 times the width of the second end.

12. The LED device according to claim 11, wherein the width of the first end is smaller than or equal to 1.5 times the width of the second end.

13. The LED device according to claim 9, wherein a width of the third end is greater than a width of the first end, a width of the fourth end is greater than a width of the second end, and a difference between the width of the third end and the width of the first end is greater than a difference between the width of the fourth end and the width of the second end and smaller than or equal to 2 times the difference between the width of the fourth end and the width of the second end.

14. The LED device according to claim 13, wherein the difference between the width of the third end and the width of the first end is smaller than or equal to 1.5 times the difference between the width of the fourth end and the width of the second end.

15. The LED device according to claim 9, wherein the CB structure is located between the first electrode and the epitaxial layer or between the epitaxial layer and the substrate.

16. The LED device according to claim 9, wherein a projection of the connecting portion of the first electrode falls within the barrier connecting portion of the CB structure, and the extending direction of the conductive finger of the first electrode is the same as the extending direction of the barrier finger of the CB structure.
